(19) United States
(12) Patent Application Publication
(10) Pub. No.: US 2011/0243216 A1
(43) Pub. Date: Oct. 6, 2011

(54) COMMUNICATION APPARATUS AND CONTROL METHOD THEREOF

(75) Inventors: Shigeyuki YOSHIOKA, Yokohama (JP); Kenta SASAKI, Yokohama (JP); Kotaro MURAKAMI, Yokohama (JP)

(73) Assignee: FUJITSU SEMICONDUCTOR LIMITED, Yokohama-shi (JP)

(21) Appl. No.: 13/073,495

(22) Filed: Mar. 28, 2011

(30) Foreign Application Priority Data
Mar. 31, 2010 (JP) 2010-080951

(51) Int. Cl. H03K 7/08

(52) U.S. Cl. 375/238

(57) ABSTRACT

A communication apparatus which receives output voltage of a direct current voltage converter, the communication apparatus includes: a modulating/demodulating circuit which demodulates a reception signal from a high-frequency transmitting/receiving circuit, modulates a transmission signal, and outputs the transmission signal to the high-frequency transmitting/receiving circuit; a communication control circuit which inputs reception data and outputs transmission data to and from the modulating/demodulating circuit and performs communication control in accordance with an reception period and a transmission period; and a direct current voltage converter control circuit which switches a direct current voltage converter, which outputs an output voltage to the communication apparatus, to pulse width modulation control in the reception period and transmission period, and switches the direct current voltage converter to pulse frequency modulation control in at least a partial period excluding the reception period and the transmission period.

### CROSS REFERENCE TO RELATED APPLICATION

This application is based upon and claims the benefit of priority from the prior Japanese Patent Application NO. 2010-080951 filed on Mar. 31, 2010, the entire contents of which are incorporated herein by reference.

### FIELD

The embodiments discussed herein are related to mobile unit communication apparatuses and control methods thereof.

### BACKGROUND

A mobile unit communication apparatus is provided in a cellular phone or an information terminal that supports WiMax. A mobile unit communication apparatus receives power supply voltage from a voltage converter which converts voltage from an external power supply such as a battery to power supply voltage for communication device. The voltage converter maintains power supply voltage to be supplied to a communication device at a desirable voltage level.

A direct current voltage converter (DCDC converter) which converts direct current voltage to direct current voltage at a different voltage level is an example of the voltage converter. The DCDC converter is an LSI device which converts voltage in an external power supply to output voltage at a different voltage level. Current is supplied from an external power supply through a switching element to an inductor on the output terminal side thereof and generates smoothed output voltage. A pulse width modulation (PWM) control and a pulse frequency modulation (PFM) control are known as control methods for the switching element. Generally, PWM control is applied when the load current is large, and PFM control is applied when the load current is small. PWM control has high responsiveness to variations in output load and generates little variations (ripple) in output voltage but consumes a larger amount of current. On the other hand, PFM control consumes a smaller amount of current but has low responsiveness and generates large variations in output voltage.

Mobile communication terminals having a DCDC converter are disclosed in Japanese Laid-open Patent Publication Nos. 2009-33591, 2002-141824, and 2008-211647.

A mobile unit communication apparatus is not performing radio transmission and reception at all times and is not performing radio transmission and reception excluding a processing period with radio transmission or reception such as cell search and position registration upon powered on and communication processing upon arrival of a signal. In a WiMAX communication method, communication frames are divided into uplink frames and downlink frames. Among the communication frames, transmission and reception regions to be used by the mobile unit communication terminal are predetermined or are designated as requested. Also in this case, the mobile unit communication apparatus is not performing transmission and reception at all times during the communication frame period.

On the other hand, a communication device within a mobile unit communication apparatus has an analog circuit such as a high-frequency transmitting/receiving unit and a digital circuit which processes a baseband signal. The analog circuit generates noise or cause a misoperation due to a ripple in power supply voltage while the digital circuit may normally operate even with some ripples in power supply voltage.

### SUMMARY

According to one aspect of the embodiments, there is provided a communication apparatus which receives output voltage of a direct current voltage converter, the communication apparatus includes: a modulating/demodulating circuit which demodulates a reception signal from a high-frequency transmitting/receiving circuit, modulates a transmission signal, and outputs the transmission signal to the high-frequency transmitting/receiving circuit; a communication control circuit which inputs reception data and outputs transmission data to and from the modulating/demodulating circuit and performs communication control in accordance with an reception period and a transmission period; and a direct current voltage converter control circuit which switches a direct current voltage converter, which outputs an output voltage to the communication apparatus, to pulse width modulation control in the reception period and transmission period, and switches the direct current voltage converter to pulse frequency modulation control in at least a partial period excluding the reception period and the transmission period.

The object and advantages of the embodiments will be realized and attained by means of the elements and combinations particularly pointed out in the claims.

It is to be understood that both the foregoing general description and the following detailed description are exemplary and explanatory and are not restrictive of the embodiments, as claimed.

### BRIEF DESCRIPTION OF DRAWINGS

FIG. 1 is an entire configuration diagram of a mobile unit communication apparatus according to an embodiment;

FIG. 2 illustrates a concrete example of a power supply unit in a mobile unit communication apparatus according to this embodiment;

FIG. 3 illustrates a partial concrete example of a high-frequency transmitting/receiving unit in a mobile unit communication apparatus of this embodiment;

FIG. 4 is a configuration diagram of a DCDC converter according to this embodiment;

FIGS. 5A and 5B illustrate operations of a DCDC converter;

FIG. 6 is a waveform diagram illustrating operations of the DCDC converter;

FIG. 7 illustrates an operation waveform when the DCDC converter is under PWM control;

FIG. 8 illustrates an operation waveform when the DCDC converter is under PFM control;

FIG. 9 is a flowchart of switching control over the DCDC converter according to this embodiment;

FIG. 10 is a flowchart illustrating schematic communication control in a mobile unit communication apparatus;

FIG. 11A and FIG. 11B illustrate a first example of communication control and pulse modulation control over a mobile unit communication apparatus; and

FIG. 12 illustrates a second example of communication control and pulse modulation control over a mobile unit communication apparatus.

### DESCRIPTION OF EMBODIMENT

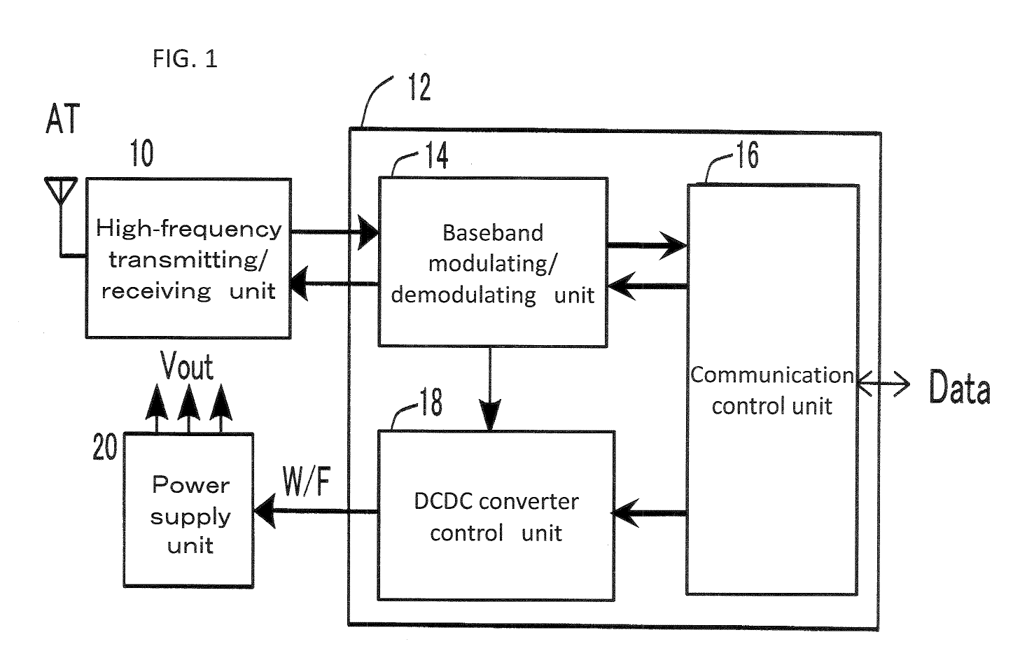

FIG. 1 is an entire configuration diagram of a mobile unit communication apparatus according to an embodiment. The mobile unit communication apparatus includes a high-frequency transmitting/receiving unit 10 which is connected to an antenna, receives a high-frequency reception signal and transmits a high-frequency transmission signal, a digital circuit unit 12 which has a baseband modulating/demodulating unit 14, a communication control unit 16 and a DCDC converter control unit 18, and a power supply unit 20.

The high-frequency transmitting/receiving unit 10 is an analog circuit which has an up-converter and power amplifier on the transmission side and a low-noise amplifier and down-converter on the reception side, as will be described below. The baseband modulating/demodulating unit 14 demodulates a reception signal from the high-frequency transmitting/receiving unit 10, modulates a transmission signal and outputs the resulting signal to the high-frequency transmitting/receiving unit 10. The communication control unit 16 processed data contained in the reception signal from the baseband modulating/demodulating unit 14, processes data to be included in a transmission signal to the baseband modulating/demodulating unit 14, and performs predetermined communication control in accordance with the inward reception period and transmission period.

The power supply unit 20 has a battery and a DCDC converter (switching regulator) which converts direct current voltage in the battery to output voltage Vout. The output voltage Vout is supplied as power supply voltage to the high-frequency transmitting/receiving unit 10, baseband modulating/demodulating unit 14, communication control unit 16 and so on.

On the basis of the reference signal for communication timing generated by the baseband modulating/demodulating unit 14 and a state signal having communication state information generated by the communication control unit 16, the DCDC converter control unit 18 generates a control signal W/F which controls the pulse control over the DCDC converter to either pulse width modulation control or pulse frequency modulation control and supplies it to the DCDC converter within the power supply unit 20.

The DCDC converter control unit 18 controls the DCDC converter to the pulse width modulation control during transmission periods and reception periods when the high-frequency transmitting/receiving unit 10 operates so as to reduce the range of variations of output voltage Vout by the DCDC converter and minimize the influence of the variations in power supply voltage to the high-frequency transmitting/receiving unit 10 which is an analog circuit. The DCDC converter control unit 18 switches the DCDC converter to the pulse frequency modulation control during at least a partial period excluding the transmission periods and reception periods to suppress the power consumption by the DCDC converter.

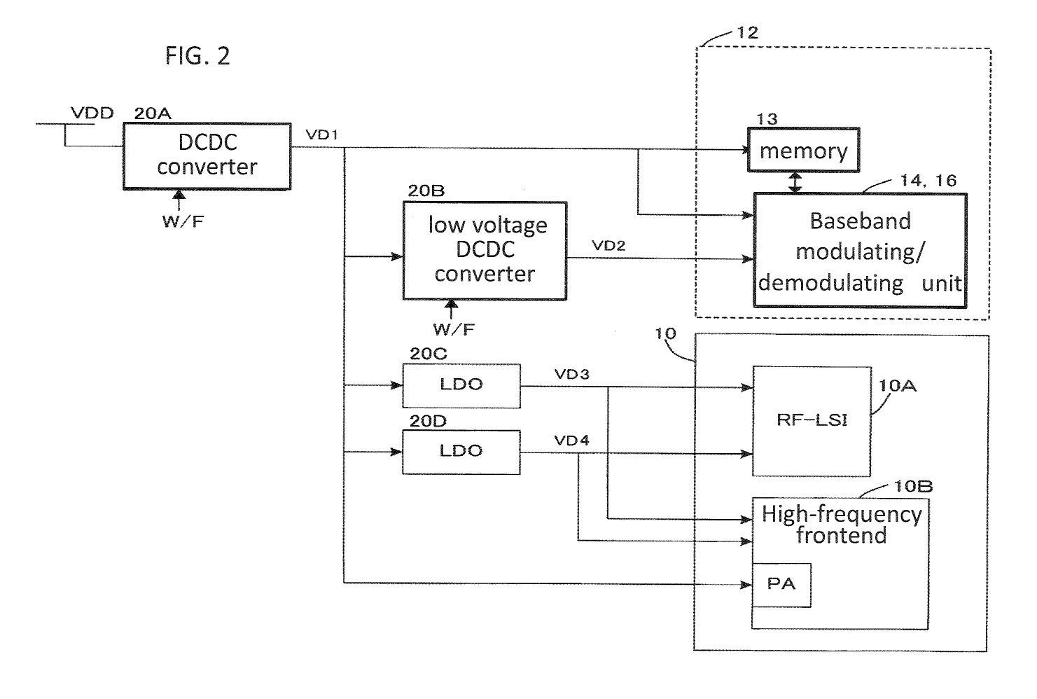

FIG. 2 illustrates a concrete example of a power supply unit in a mobile unit communication apparatus according to this embodiment. In the concrete example in FIG. 2, the power supply unit 20 has a DCDC converter (switching regulator) 20A which generates a first output voltage VD1 from external power supply VDD such as a battery, a low voltage DCDC converter (switching regulator) 20B which generates a second output voltage VD2 from the first output voltage VD1, and low dropout regulators (series regulators) 20C and 20D which generate third and fourth output voltages VD3 and VD4 from the first output voltage VD1.

These generated output voltages VD1 to VD4 are supplied to a memory 13, the baseband modulating/demodulating unit 14 and communication control unit 16 within the digital circuit unit 12 and a high-frequency LSI 10A and high-frequency frontend 10B having a power amplifier PA within the high-frequency transmitting/receiving unit 10 which is an analog circuit in the manner as illustrated. In FIG. 2, a DCDC converter control unit within the digital circuit unit 12 is omitted.

The DCDC converters 20A and 20B which are switching regulators are used as power supply voltage regulators for a load circuit having relatively larger load current. On the other hand, the series regulators 20C and 20D generate output voltages VD3 and VD4 resulting from reduction of input voltage without any switching operation and are used as power supply voltage regulators for a load circuit having relatively smaller load current.

In the example in FIG. 2, the output voltages VD1 and VD2 of the switching regulators (DCDC converters) 20A and 20B are supplied to the digital circuit unit 12 and the power amplifier PA within the RF transmitting/receiving unit 10 while the output voltages VD3 and VD4 of the series regulators 20C and 20D are supplied to the high-frequency transmitting/receiving unit 10. The DCDC converters 20A and 20B receive a control signal W/F from the DCDC converter control unit 18 in FIG. 1, and the switching control is changed to the PWM control or PFM control.

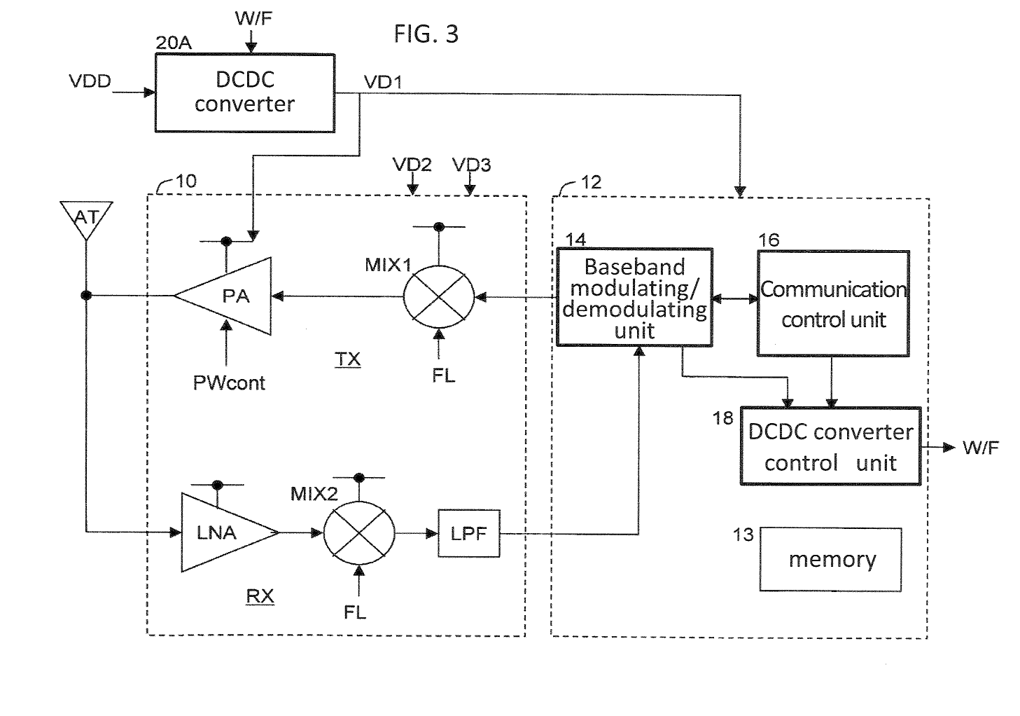

FIG. 3 illustrates a partial concrete example of the high-frequency transmitting/receiving unit 10 in a mobile unit communication apparatus of this embodiment. The high-frequency transmitting/receiving unit 10 has a transmitting circuit TX having a mixer MIX1 which up-converts a transmission signal modulated by the baseband modulating/demodulating unit 14 with a local frequency FL and a power amplifier PA which amplifies the mixer output and a receiving circuit RX having a low-noise amplifier LNA which amplifies a reception signal from the antenna AT a mixer MIX2 which down-converts it with the local frequency FL and a low-pass filter LPF.

The power amplifier PA within the transmitting circuit TX receives the output voltage VD1 from the DCDC converter 20A as power supply, and the gain is controlled in accordance with the power control signal PWcont from the communication control unit 16. The gain of the power amplifier PA is controlled properly with a power control signal PWcont based on the transmission power instructed from the base station.

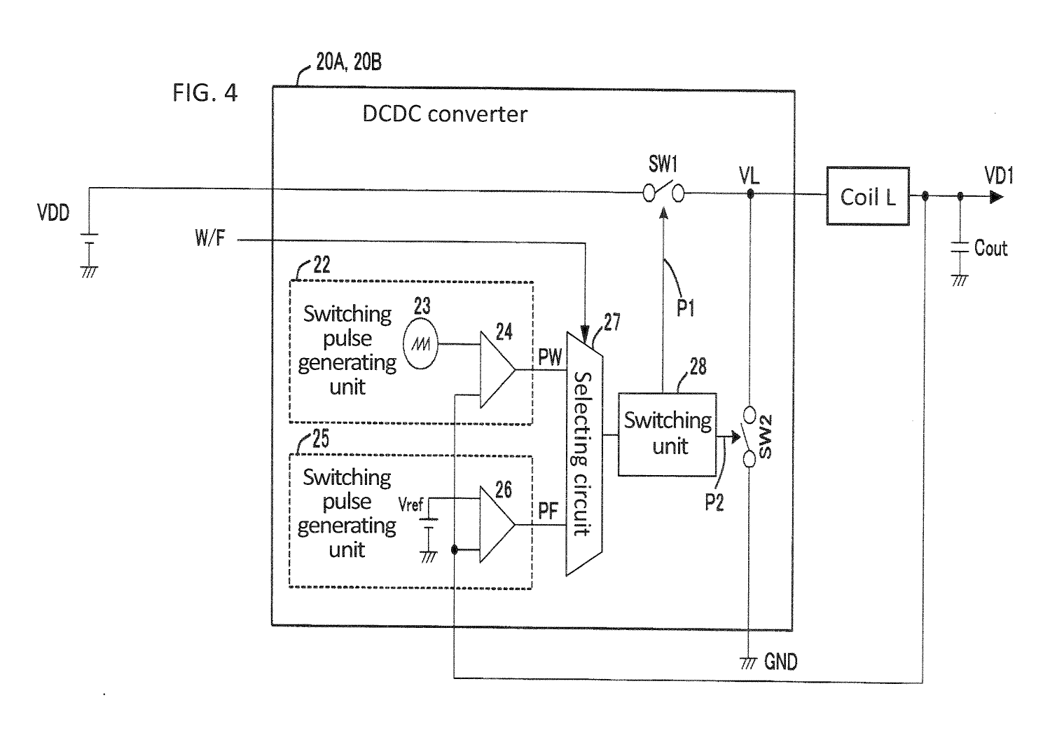

FIG. 4 is a configuration diagram of a DCDC converter according to this embodiment. Each of the DCDC converters 20A and 20B has a first switch SW1 connected to an external power supply VDD and a second switch SW2 connected to a ground GND. An output coil L connected to connection nodes (VL) of the switches SW1 and SW2 and a smoothing capacitor Cout connected to the output coil L are externally provided.

The DCDC converter further has a switching unit 28 which supplies control pulses P1 and P2 to the switches SW1 and SW2 and controls the conduction of the switches. The DCDC converter further has a generating unit 22 which generates a switching pulse PW for PWM control, a generating unit 25 which generates a switching pulse PF for PFM control, and a selecting circuit 27 which selects one of the switching pulses PW and PF in accordance with the control signal W/L.

The switching pulse generating unit 22 for PWM control has a triangular wave generating unit 23 which generates triangular waves at constant periods, and a pulse generating unit 24 which compares the output voltage VD1 and the voltage of the triangular wave signal and generates a PWM control switching pulse PW having a pulse width at a period with high voltage of the triangular wave signal. The PWM control switching pulse PW has a constant period, and the pulse width increases as the output voltage VD1 decreases. On the other hand, the PFM control switching pulse generating unit 25 has a pulse generating unit 26 which compares the output voltage VD1 and a reference voltage Vref. The pulse generating unit 26 generates a PFM control switching pulse PF having a longer period if the output voltage VD1 has a constant pulse width and is lower than the reference voltage Vref. On the other hand, the pulse generating unit 26 generates a PFM control switching pulse PF having a shorter period if the output voltage VD1 is higher than the reference voltage Vref.

The selecting circuit 27 selects either control switching pulse PW or PF in accordance with the control signal W/F. On the basis of the pulse PW or PF selected by the selecting circuit 27, the switching unit 28 generates a positive-phase-sequence control pulse P1 and a negative-phase-sequence control pulse P2 about the pulse and controls the conduction of the switches SW1 and SW2 in negative phase sequences.

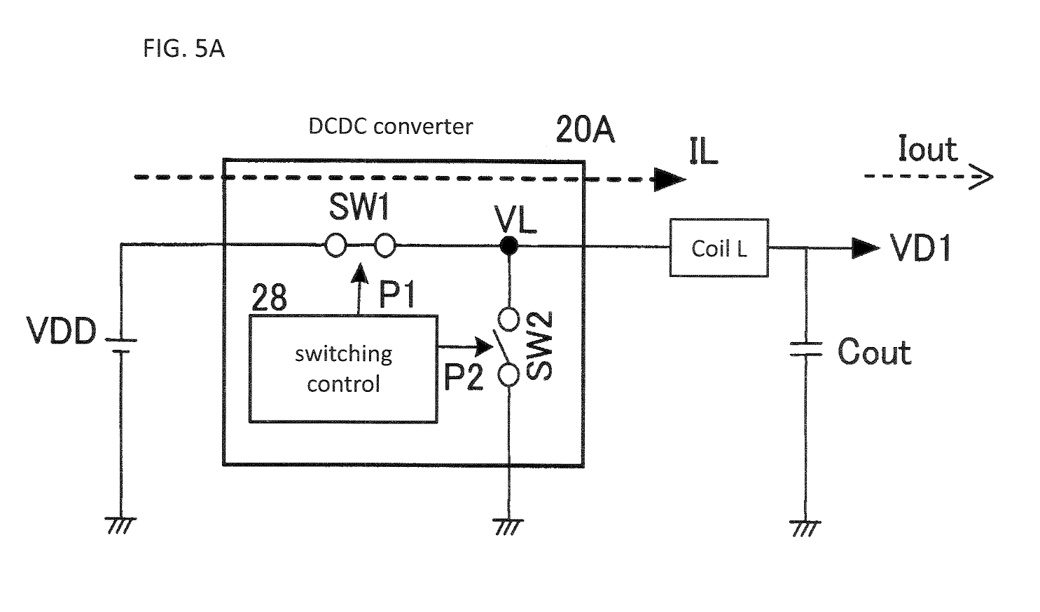

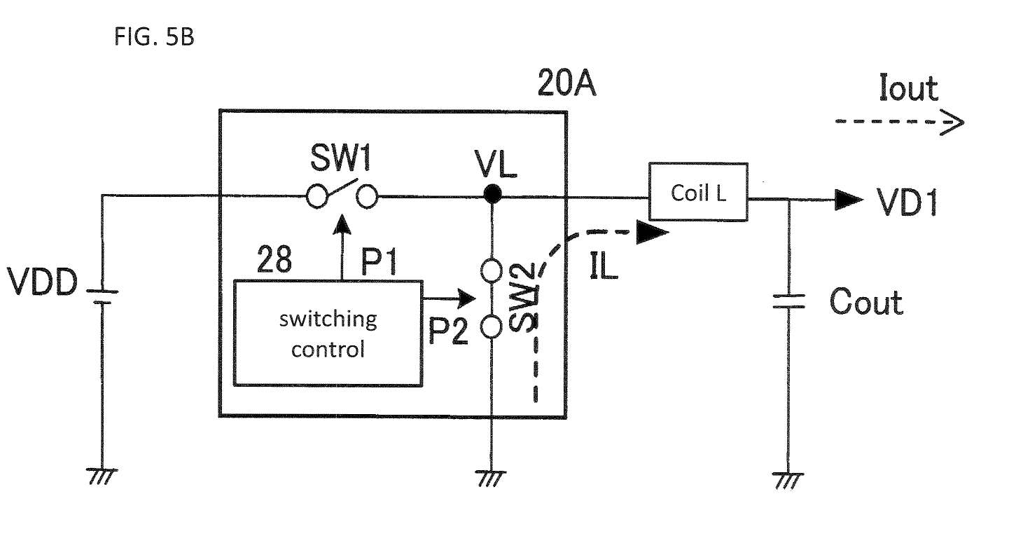

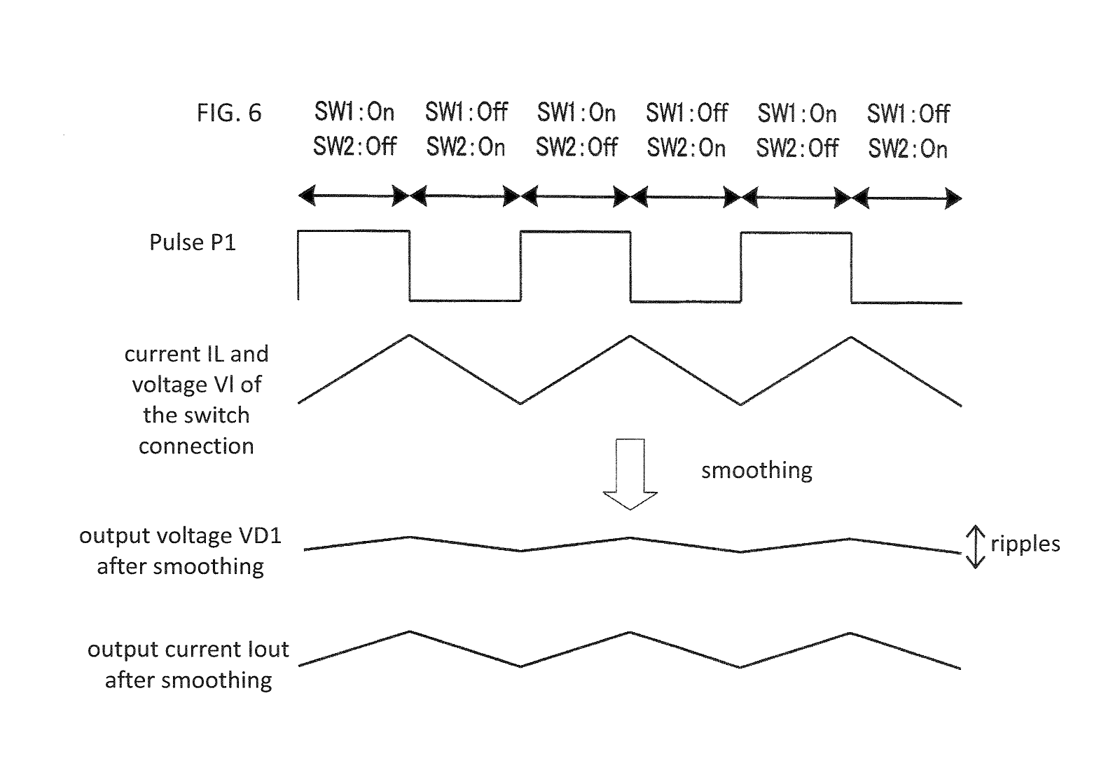

FIGS. 5A and 5B illustrate operations of the DCDC converter. FIG. 6 is a waveform diagram illustrating operations of the DCDC converter. The first and second switches SW1 and SW2 in the DCDC converter alternately repeat the conduction and non-conduction with the control pulses P1 and P2. The control pulses P1 and P2 are reverse to each other.

In FIG. 5A, the first switch SW1 has a conduction state while the second switch SW2 has a non-conduction state. In these states, the current IL which flows from an external power supply VDD through the switch SW1 to a coil L gradually increases, and voltage VL at the switch connection node also increases. From the current IL, energy is stored in a magnetic flux form in the coil L.

On the other hand, in FIG. 5B, the first switch SW1 has a non-conduction state while the second switch SW2 has a conduction state. Though the switch connection node is connected to the ground GND through the second switch SW2, the energy stored in the coil L allows the current IL to continuously flow through the switch SW2. However, the current IL gradually decreases, and the voltage VL at the switch connection node also gradually decreases.

As illustrated in FIG. 6, during the period when the pulse P1 which turns on (ON) the first switch SW1 has a H level, the current IL and the voltage VL of the switch connection node increase (in the state in FIG. 5A). When the pulse P1 has an L level, the current IL and voltage VL decrease (in the state in FIG. 5B). The increase and decrease in voltage VL are smoothed by a smoothing filter including the coil L and the smoothing capacitor Cout, reducing ripples (variations) in output voltage VD1 and output current Iout. In this way, the DCDC converter being a switching regulator causes ripples (variations) in output voltage VD1.

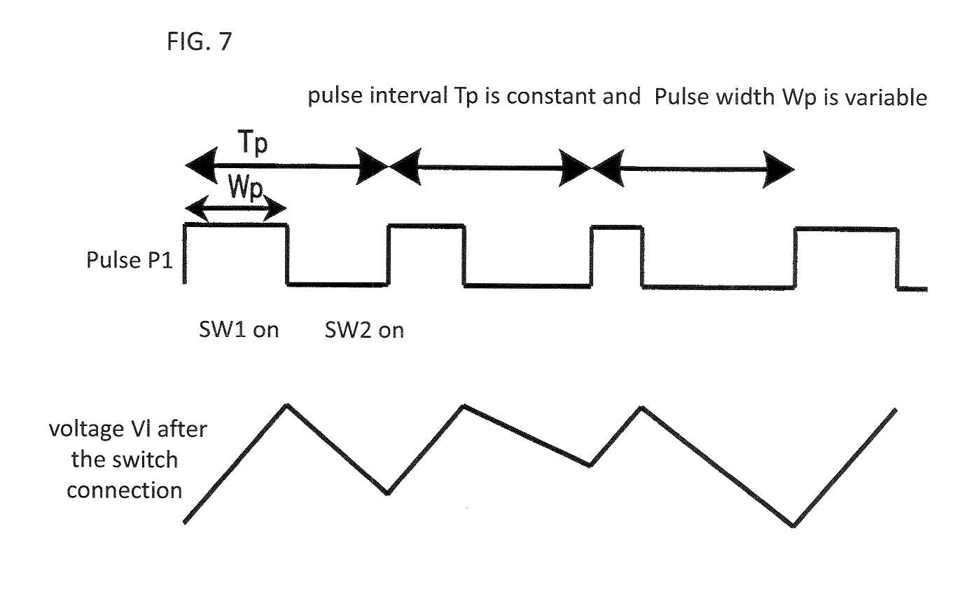

FIG. 7 illustrates an operation waveform when the DCDC converter is under PWM control. Under PWM control, the pulse P1 which controls the switch SW1 has constant pulse intervals Tp, and the pulse width Wp is variably controlled in accordance with the output voltage VD1. In other words, as the output voltage VD1 decreases, the pulse width Wp increases. As the output voltage VD1 increases, the pulse width Wp decreases. As a result, the voltage VL at the switch connection point increases during the period corresponding to the variable pulse width Wp at the constant pulse intervals Tp and decreases during the period when the pulse P1 has L (that is, the period when the pulse P2 has H). Accordingly, the voltage VL may be controlled such that the range of changes in voltage VL may be small and higher responsiveness to the changes in the output load may be provided. However, since PWM control may requeste frequent switching operations, the current consumption by the DCDC converter is relatively large.

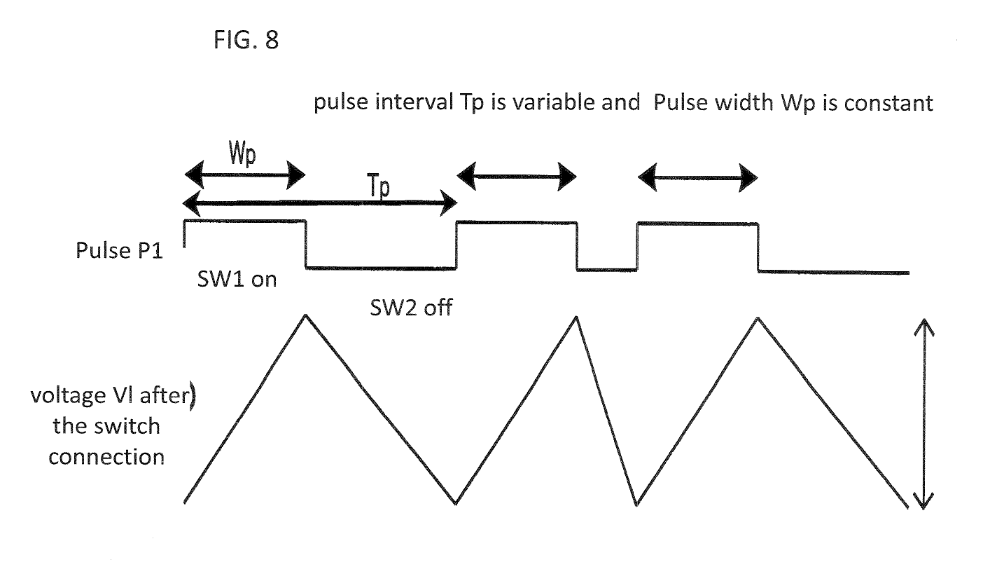

FIG. 8 illustrates an operation waveform when the DCDC converter is under PFM control. Under PFM control, the pulse P1 which controls the switch SW1 has a constant pulse width Wp, and the pulse interval Tp is variably controlled in accordance with the output voltage VD1. In other words, as the output voltage VD1 decreases, the pulse interval Tp decreases. As the output voltage VD1 increases, the pulse interval Tp increases. As a result, the voltage VL at the switch connection point increases during the period corresponding to the constant pulse width Wp at the variable pulse intervals Tp and decreases during the period when the pulse P1 has L (that is, the period when the pulse P2 has H). Accordingly, the voltage VL may be controlled such that the range of changes in voltage VL may be larger than PWM control and lower responsiveness to the changes in the output load may be provided. However, since PFM control may requeste less frequent switching operations, the current consumption by the DCDC converter is relatively small.

As illustrated in FIG. 6, since the output voltage VD1 in the DCDC converter is smoothed voltage VL at the switch connection point illustrated in FIG. 7 and FIG. 8, the range of ripples (variations) in output voltage VD1 is small under PWM and is large under PFM.

Generally, the DCDC converter automatically switches between PWM control and PFM control for switching control on the basis of the load current. Generally, for high load current, PWM control with frequent current supply is selected. For low load current, PFM control with less frequent current supply is selected.

However, when the DCDC converter is used as a power supply regulator in a mobile unit communication apparatus, selecting either PWM or PFM in accordance with the magnitude of the load current may not typically be proper. In other words, in order to minimize the current consumption by the DCDC converter, PWM control with large current consumption by the DCDC converter is desirably selected during a period when the communication apparatus needs to minimize the ripples in power supply voltage. PFM control even with larger current consumption is desirably selected during a period when large ripples are acceptable. Quick switching is also difficult under the control which switches between the control methods according to the magnitude of the load current.

Minimizing the ripples in power supply voltage may be requested when a transmission/reception operation is performed by the high-frequency transmitting/receiving unit 10. This is because large ripples in power supply voltage may cause power supply noise, and the power supply noise is superposed on the signal in the high-frequency transmitting/receiving unit 10 which is an analog circuit and may cause a misoperation. The power supply noise may cause noise in a transmission signal, and thus noise is amplified in a power amplifier. On the other hand, large ripples in power supply voltage may be acceptable in a memory, a baseband modulating/demodulating unit or a communication control unit which is a digital circuit. Few misoperations may be caused even by the power supply noise to an extent in a digital circuit.

For example, in start processing involving the start of power supply, a processor performs frequent memory access to download a program from a memory, causing large load current. However, during the start processing, since the high-frequency transmitting/receiving unit 10 does not perform a transmission/reception operation, the DCDC converter may be PFM-controlled without the necessity of PWM control. Conversely, even with small load current, when the high-frequency transmitting/receiving unit operates with a transmission/reception operation, the DCDC converter is desirably PWM-controlled.

According to this embodiment, during a transmission period or a reception period when the high-frequency transmitting/receiving unit performs a transmission operation or a reception operation, the DCDC converter is PWM-controlled. During a period excluding the transmission period and reception period, the DCDC converter is PFM-controlled. Thus, the power consumption by the DCDC converter may be minimized without any difficulties in transmission and reception operations by the communication apparatus.

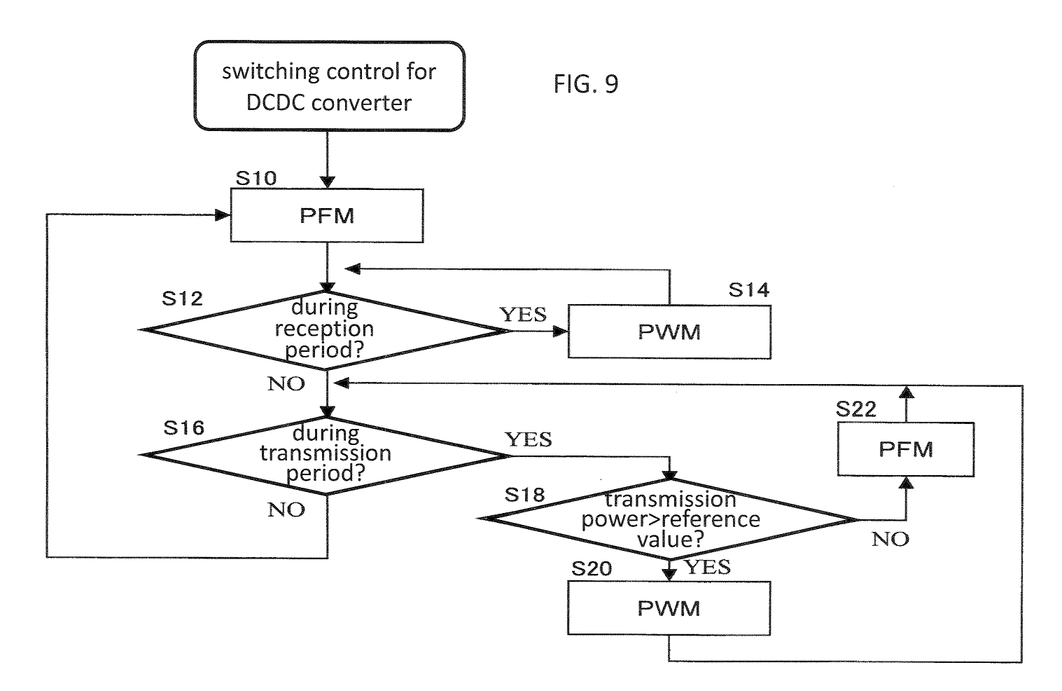

FIG. 9 is a flowchart of switching control over the DCDC converter according to this embodiment. The DCDC converter control unit 18 switches the DCDC converter to PFM control from the start of power supply (S10). The DCDC converter control unit 18 acquires the timing of the transmission period or reception period from a reference timer signal which notifies a frame synchronization timing from the baseband modulating/demodulating unit 14 and a communication state signal from which a transmission period or a reception period is identified from the communication control unit 16.

If it is during a reception period (YES in S12), the DCDC converter control unit 18 switches to the PWM control (S14). If it is during a transmission period (YES in S16), the DCDC converter control unit 18 switches to PWM control (S20). If it is a period excluding transmission and reception periods, the DCDC converter control unit 18 switches back to PFM control (S10). Even if it is during a transmission period (YES in S16) but if the transmission power is not higher than a reference value (NO in S18), the DCDC converter control unit 18 switches to PFM control (S22). If the transmission power is higher than the reference value (YES in S18), the DCDC converter control unit 18 switches to PWM control (S20).

As illustrated in FIG. 3, in the transmitting unit TX within the high-frequency transmitting/receiving unit 10, the power amplifier PA in the final stage amplifies an input transmission signal with a gain according to the power control signal PWcont. Thus, if the power control signal PWcont requests power that is higher than the reference value, the noise component caused in the transmission signal by power supply noise is amplified largely in the power amplifier PA. Therefore, PWM control with small variations in power supply is preferable for a small noise component in a transmission signal. However, if the power control signal PWcont requests low power that is not higher than the reference value, the noise component is not much amplified in the power amplifier PA. Thus, PFM control with large variations in power supply may cause few difficulties in transmission operations.

Hereinafter, the selection of PWM control or PFM control in a specific communication control example will be described in detail.

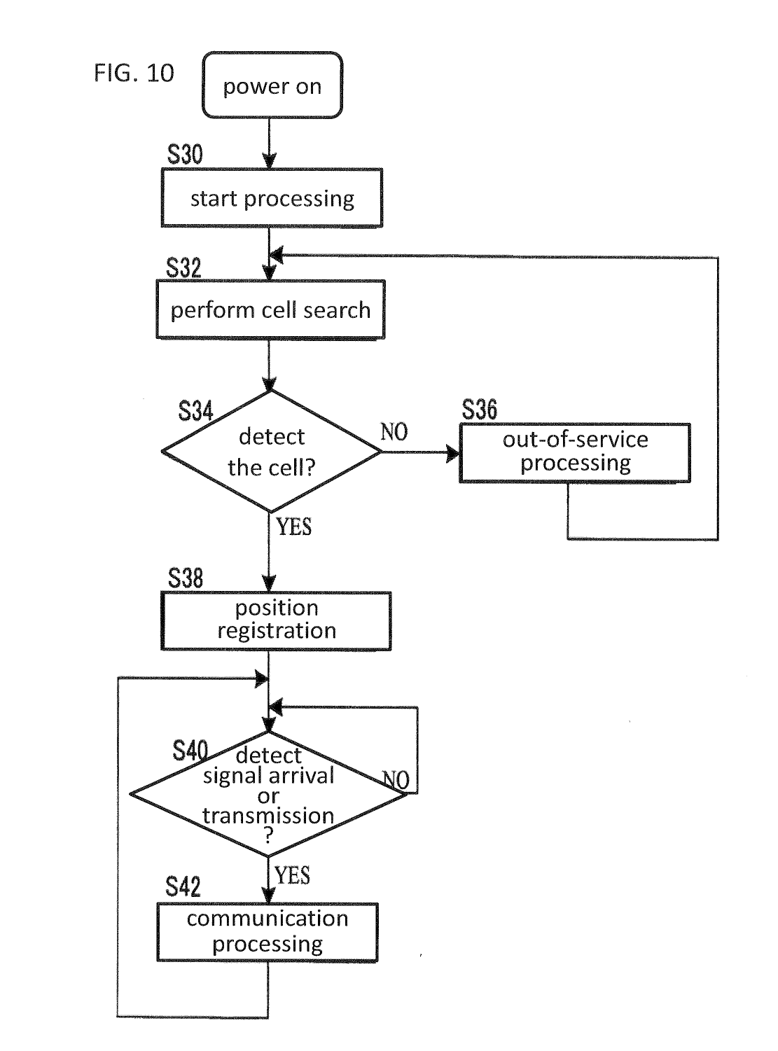

FIG. 10 is a flowchart illustrating schematic communication control in a mobile unit communication apparatus. Upon powered on, an initial operation is performed in which a CPU included in the communication control unit 16 and DCDC converter control unit 18 within a mobile unit communication apparatus performs start processing such as loading a program from a memory and setting a variable (S30).

Next, the mobile unit communication apparatus performs cell search which detects the cell region in which the local station positions (S32). In the cell search, the communication control unit 16 monitors reception power by scanning the local frequency FL in the receiving circuit RX within the high-frequency transmitting/receiving unit 10 within the frequency band of a carrier, detects the frequency with the largest reception power, and detects that the local station positions in the cell area to which the frequency is allocated. Thus, in the cell search, the high-frequency transmitting/receiving unit 10 performs the reception operation.

If the cell search detects the cell (YES in S34), the mobile unit communication apparatus performs an authentication and registration procedure which is called position registration with a management center for the network (S38). In this case (No in S34), out-of-service processing is performed in which the mobile unit communication apparatus waits for a predetermined period of time (S36). In the out-of-service processing, the mobile unit communication apparatus is controlled to a low-power-consumption state and only waits for a predetermined period of time on the basis of a timer, and no transmission and reception are performed.

Once the position registration is performed (S38), the mobile unit communication apparatus is enabled to receive and transmit signals. When the arrival of a signal transmitted from a network is detected, communication processing including transmission and reception operations is performed. When a signal transmission from a user is detected, the communication processing including transmission and reception operations is also performed (S40 and S42). When the transmission and reception operations end, the mobile unit communication apparatus waits for the detection of signal arrival or transmission.

In the waiting state, reception and transmission are performed periodically on the basis of a communication control method. After the position registration, transmission and reception operations are performed for monitoring signal arrival information every management unit of a network time called a frame number, for example. Thus, as described above, the DCDC converter control unit 18 is given a reference timer signal indicating a frame synchronization timing from the baseband modulating/demodulating unit 14 and a state signal notifying a communication state from the communication control unit 16. Thus, on the basis of the signals, the DCDC converter control unit 18 may grasp the reception period and the transmission period. During the reception period and transmission period, the DCDC converter is PWM-controlled. During a certain period excluding the reception period and transmission period, the DCDC converter is PFM-controlled. However, if the transmission power is lower than the reference value even during the transmission period, PFM control is selected.

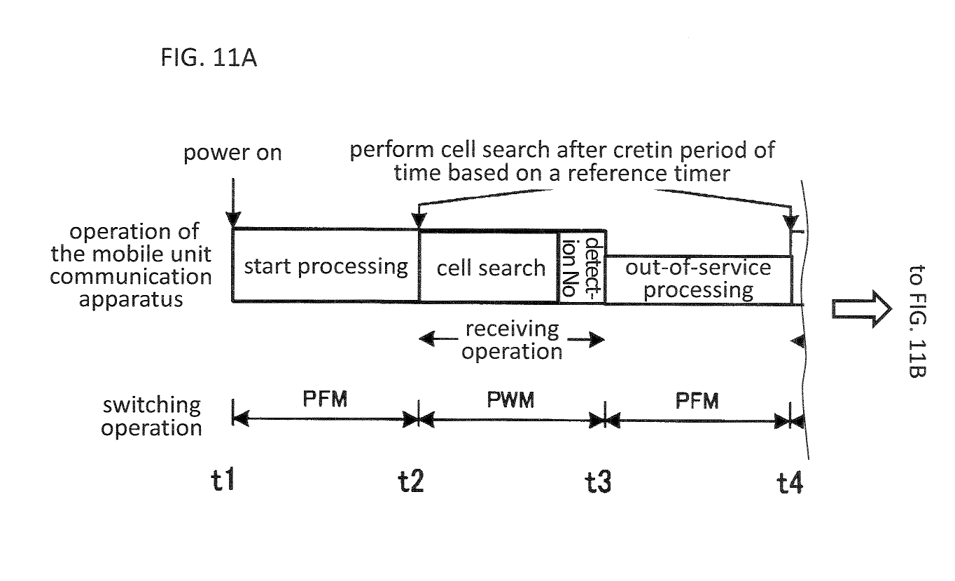

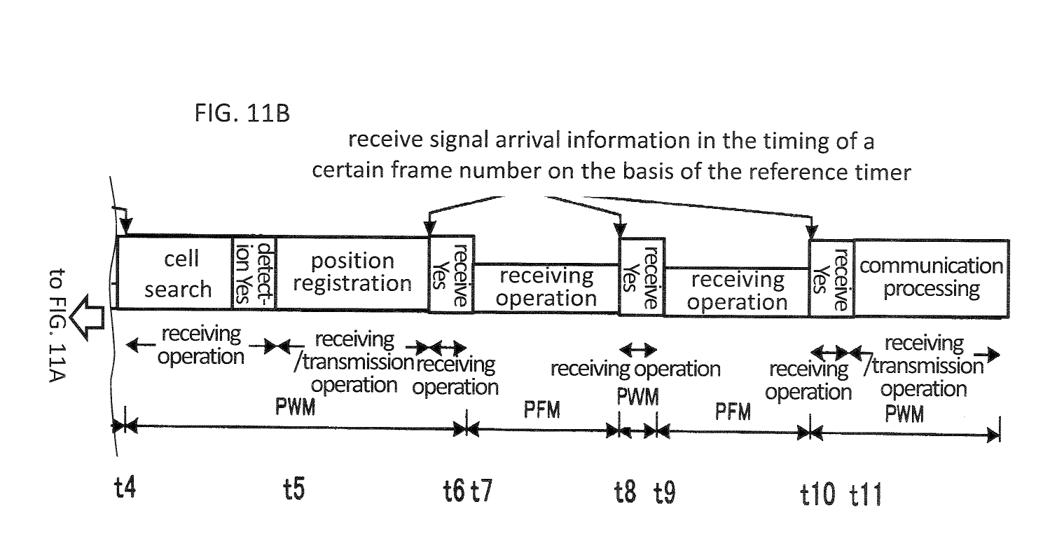

FIG. 11A and FIG. 11B illustrate a first example of communication control and pulse modulation control over the mobile unit communication apparatus. The communication control corresponds to the communication method of the cellular phone. When the power supply is turned on at a time t1, the processor performs start processing. During the period for the start processing, power consumption increases because of frequent memory accesses, for example, but the DCDC converter is PFM-controlled.

At a time t2, the mobile unit communication apparatus performs the cell search. Since a reception operation is involved during this period, the DCDC converter is PWM-controlled. If the first cell search does not detect radio waves from a cell, the out-of-service processing is performed from the time t3. The cell search is performed again from a time t4 after a lapse of a predetermined period of time based on a reference timer. In the out-of-service processing, since the mobile unit communication apparatus has a low-power consumption state and does not perform transmission and reception operations, it is PFM-controlled.

In the example in FIG. 11A and FIG. 11B, the second cell search at the time t4 detects the cell, and the position registration processing is performed from a time t5. The position registration processing involves transmission/reception operations in order to register the cell in which the communication apparatus positions with a network center through the base station. Thus, the DCDC converter is PWM-controlled during the period for the cell search from the time t4 and the period for the position registration processing from the time t5.

After the position registration completes, the mobile unit communication apparatus receives signal arrival information in the timing of a predetermined frame number assigned to the mobile unit communication apparatus on the basis of the reference timer and checks whether any signal destined to the local station has arrived or not. For example, in FIG. 11A and FIG. 11B, the signal arrival checking is performed at the times t6, t8, and t10. Since the signal arrival checking involves a reception operation, the DCDC converter is PWM-controlled at the times t6, t8 and t10.

If the signal arrival checking detects no signal arrival, the waiting processing is performed at times t7 and t9. In the waiting processing, the mobile unit communication apparatus has the low-power-consumption state without transmission and reception operations and waits until the next frame number timing. Thus, the DCDC converter is PFM-controlled. If the signal arrival checking detects some signal arrival, the communication processing involving transmission and reception operations is performed at a time t11, and the DCDC converter is PWM-controlled.

Though not illustrated, if signal transmission is requested by a user, the communication processing involving transmission and reception operations is performed after that, and the DCDC converter is PWM-controlled.

In the manner as described above, in the mobile unit communication apparatus, a transmission operation, a reception operation and non-transmission/reception operation are switched in short periods of time under the series of communication controls. According to this embodiment, the DCDC converter control unit 18 monitors those periods, and the DCDC converter is quickly switched between PWM control and PFM control with the control signal W/F. Thus, the power consumption by the DCDC converter may be suppressed without difficulties in the communication processing.

When a transmission operation or a reception operation is repeated with a short interval between the repeated operations, the DCDC converter control unit 18 may keep PWM control and suppress the variations in power-supply voltage caused by switching the pulse control. However, during at least a partial period or desirably all period without transmission and reception operations, PFM is desirably selected to suppress the current consumption by the DCDC converter.

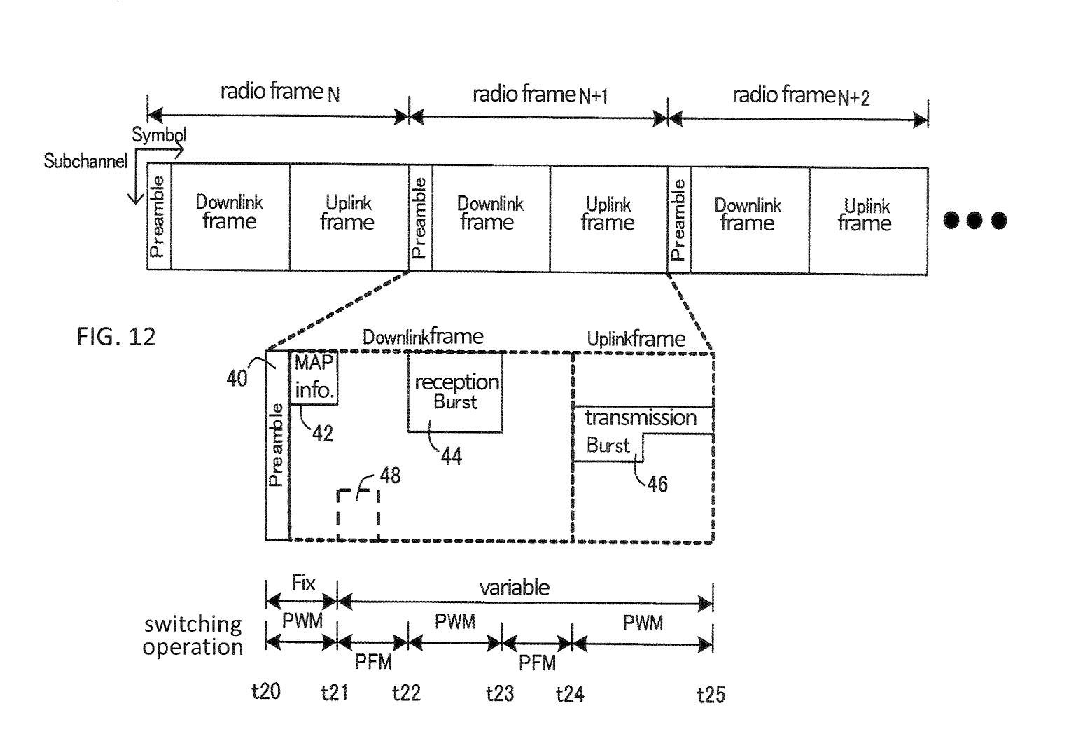

FIG. 12 illustrates a second example of communication control and pulse modulation control over a mobile unit communication apparatus. The communication control corresponds to a WiMAX communication method. A WiMAX communication method applies OFDMA communication, and radio frames N, N+1, and N+2 having a fixed length are repeated, as illustrated in FIG. 12. For the radio frames, the horizontal-axis direction corresponds to a symbol direction, and the vertical-axis direction corresponds to a sub-channel (OFDM sub-carrier) direction.

A radio frame includes a preamble, a downlink frame and an uplink frame. The preamble assigned to all sub-channels at the beginning of a radio frame may include a known synchronization signal bit, for example. Subsequent to the preamble, map information region 42 having a fixed symbol length is assigned to a fixed sub-channel. The map information region 42 contains information on a reception burst region 44 within the downlink frame assigned to a terminal and information on a transmission burst region 46 within the uplink frame.

Thus, the period from the time t20 to the time t21 is a fixed period for a preamble 40 and the map information region 42 from the beginning of a radio frame. After the time t21, burst regions 44 and 46 assigned to a local station are variable depending on the map information 42. Thus, on the basis of the map information 42, the communication control unit 16 may identify the time zones of the reception burst region 44 and transmission burst region 46 destined to the local station.

Accordingly, the DCDC converter control unit 18 is given a radio frame timer signal which notifies the starting time of a radio frame from the baseband modulating/demodulating unit 14, is given time information on the reception burst region and transmission burst region destined to the local station based on the map information from the communication control unit 16, and, on the basis of the given information, grasps the time zones in which the mobile unit communication apparatus performs a reception operation and a transmission operation.

As illustrated in FIG. 12, the DCDC converter control unit 18 PFM-controls the DCDC converter from the time t21, switches to PWM control in the period from the time t22 to the time t23 in the reception burst 44 destined to the local station, and switches to PFM control at the time t23. The DCDC converter control unit 18 switches the DCDC converter to PWM control in the period from the time t24 to the time t25 in the transmission burst 46 assigned to the local station within the downlink frame.

In this way, since WiMAX is a type of time-division multi-access method, and the time zone for a reception burst destined to a local station in a partial time zone within a radio frame and the time zone for a transmission burst may only be used by the high-frequency transmitting/receiving unit to perform reception processing or transmission processing. In the other time zones, the mobile unit communication apparatus has a standby state in which neither transmission processing nor reception processing is performed even within a radio frame. Thus, the DCDC converter is PWM-controlled only in the time zone for a reception burst and the time zone for a transmission burst within a radio frame, and the control is switched to PFM control as much as possible in the other time zones.

In the WiMAX communication method, the DCDC converter control unit 18 is given a radio frame timer signal containing time information on a radio frame from the baseband modulating/demodulating unit 14, is given a burst assignment information signal destined to a local station acquired by analyzing map information from the communication control unit 16, detects, on the basis of the signals, the time zones in which the local station performs a reception operation and a transmission operation, and controls the DCDC converter so as to switch to PWM control or PFM control, as illustrated in FIG. 12.

If the transmission power is not higher than the reference value in the time zone for the transmission burst 46, the ripples in power supply voltage caused by the pulse control is not significant as described above. Therefore, PFM control is desirable.

As illustrated in FIG. 12, a notification burst 48 may be assigned to within a downlink frame. The notification burst 48 is used by a base station to inform time information, for example, to all terminals. Since the notification burst 48 also corresponds to the reception burst destined to the local station, the DCDC converter is preferably PWM-controlled.

As described above, according to a mobile unit communication apparatus of this embodiment, the pulse control over a DCDC converter may be properly switched to PWM or PFM in accordance with the communication state, and the current consumption by the DCDC converter may be suppressed as much as possible without difficulties in communication processing.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a depicting of the superiority and inferiority of the invention. Although the embodiments of the present invention have been described in detail, it should be understood that the various changes, substitutions, and alterations could be made hereto without departing from the spirit and scope of the invention.

What is claimed is:

1. A communication apparatus which receives output voltage of a direct current voltage converter, the communication apparatus comprising:
a modulating/demodulating circuit which demodulates a reception signal from a high-frequency transmitting/receiving circuit, modulates a transmission signal, and outputs the transmission signal to the high-frequency transmitting/receiving circuit;
a communication control circuit which inputs reception data and outputs transmission data to and from the modulating/demodulating circuit and performs communication control in accordance with an reception period and a transmission period; and
a direct current voltage converter control circuit which switches a direct current voltage converter, which outputs an output voltage to the communication apparatus, to pulse width modulation control in the reception period and transmission period, and switches the direct current voltage converter to pulse frequency modulation control in at least a partial period excluding the reception period and the transmission period.

2. The mobile circuit communication apparatus according to claim 1, wherein the communication control circuit performs the communication control in synchronism with a communication frame having a preamble period, a downlink frame and an uplink frame; and
the reception period includes one of the preamble period, map information reception period within the downlink frame and a reception burst period to the local station, and the transmission period includes a transmission burst period assigned to the local station within the uplink frame.

3. The mobile circuit communication apparatus according to claim 2, wherein the direct current voltage converter control circuit switches the direct current voltage converter to pulse frequency modulation control in at least a partial period of the period excluding the map information reception period, the reception burst period to the local station, and the transmission burst period even in the downlink frame and uplink frame.

4. The mobile circuit communication apparatus according to claim 1,
wherein the communication control circuit controls one of start processing including loading a program from memory in starting, cell search which searches the frequency of a cell where the local station positions on the basis of the reception power, position registration which registers information on the detected cell through a base station, signal arrival processing which receives or transmits a signal upon arrival of a signal therefor, and outward communication processing which receives or transmits a signal in response to a local station communication request; and
the reception period includes one period of the cell search, position registration, signal arrival processing and outward communication processing, and the transmission period includes one period of the position registration, signal arrival processing, and outward communication processing.

5. The mobile circuit communication apparatus according to claim 4, wherein the direct current voltage converter control circuit switches the direct current voltage converter to pulse frequency modulation control in the period for the start processing.

6. The mobile circuit communication apparatus according to claim 1, wherein the direct current voltage converter control circuit switches the direct current voltage converter to pulse frequency modulation control if the transmission power by the high-frequency transmitting/receiving circuit is lower than a predetermined value even during the transmission period.

7. The mobile circuit communication apparatus according to claim 1, the apparatus further comprising the direct current voltage converter which converts direct current voltage to output voltage and the high-frequency transmitting/receiving circuit which receives a high-frequency reception signal and transmits a high-frequency transmission signal, wherein the output voltage by the direct current voltage converter is supplied to the high-frequency transmitting/receiving circuit, the modulating/demodulating circuit and the communication control circuit.

8. The mobile circuit communication apparatus according to claim 1, wherein the direct current voltage converter has a switch connected to between an external power supply and an output terminal, and a switching control circuit which generates switching pulses that bring the switch into conduction and outputs the pulses to the switch; and
the switching control circuit under the pulse width modulation control generates pulses having a pulse width according to the output voltage every predetermined period as the switching pulses and under the pulse frequency control generates pulses having a predetermined pulse width in periods according to the output voltage as the switching pulses.

9. A control method for a direct current voltage converter for a communication apparatus, in which the direct current voltage converter supplies output voltage to the mobile circuit communication apparatus, and the mobile circuit communication apparatus has a high-frequency transmitting/receiving circuit which receives the output voltage from the direct current voltage converter, receives a high-frequency reception signal and transmits a high-frequency transmission signal, a modulating/demodulating circuit which demodulates a reception signal from a high-frequency transmitting/receiving circuit, modulates a transmission signal, and outputs them to the high-frequency transmitting/receiving circuit, and a communication control circuit which inputs reception data and outputs transmission data to and from the modulating/demodulating circuit and performs communication control in accordance with an inward reception period and a transmission period, the method comprising:
switching the direct current voltage converter to pulse width modulation control in the reception period and transmission period; and
switching the direct current voltage converter to pulse frequency modulation control in at least a partial period excluding the reception period and transmission period.

10. The control method for the direct current voltage converter for a communication apparatus according to claim 9, wherein the communication control circuit performs the communication control in synchronism with a communication frame having a preamble period, a downlink frame and an uplink frame;
the reception period includes one of the preamble period, map information reception period within the downlink frame and a reception burst period to the local station, and the transmission period includes a transmission burst period assigned to the local station within the uplink frame.

11. The control method for the direct current voltage converter for a communication apparatus according to claim 9, wherein the communication control circuit controls one of start processing including loading a program from memory in starting, cell search which searches the frequency of a cell where the local station positions on the basis of the reception power, position registration which registers information on the detected cell through a base station, signal arrival processing which receives or transmits a signal upon arrival of a signal therefor, and outward communication processing which receives or transmits a signal in response to a local station communication request; and
the reception period includes one period of the cell search, position registration, signal arrival processing and outward communication processing, and the transmission period includes one period of the position registration, signal arrival processing, and outward communication processing.
